(19) United States
(12) Patent Application Publication
(10) Pub. No.: US 2026/0089977 A1
(43) Pub. Date: Mar. 26, 2026

(54) SEMICONDUCOR DEVICE AND METHOD OF FABRICATING THE SAME

(71) Applicant: EUIPIL KWON, SAN JOSE, CA (US)

(72) Inventor: EUIPIL KWON, SAN JOSE, CA (US)

(21) Appl. No.: 19/403,876

(22) Filed: Nov. 30, 2025

Related U.S. Application Data
(62) Division of application No. 17/882,545, filed on Aug. 6, 2022.

(51) Int. Cl. H10B 63/00; H10B 61/00; H10B 63/10; H10B 99/00; H10N 50/01; H10N 50/10; H10N 50/80; H10N 70/00; H10N 70/20

(52) U.S. Cl. CPC H10B 63/32; H10B 61/22; H10B 63/10; H10B 63/20; H10B 99/16; H10B 99/22; H10N 50/01; H10N 50/10; H10N 50/80; H10N 70/011; H10N 70/231; H10N 70/253; H10N 70/841

(57) ABSTRACT

Provided are a semiconductor device and a method of fabricating the same.

The semiconductor device includes a semiconductor substrate, a first and a second diffusion region formed under a surface of the semiconductor substrate, a gate and a sidewall spacer stacked on the semiconductor substrate, wherein the first diffusion region is at least one active region not being intersected by the gate and the sidewall spacer, wherein the second diffusion region includes a part of an active region intersecting the gate and the sidewall spacer, wherein there is no gate insulating layer between the gate and the semiconductor substrate.

### BACKGROUND

### 1. Field

Embodiments of the inventive concept relate to a semiconductor device and a method of fabricating the same and, more particularly, to a semiconductor device including a transistor configured with a smaller area and with a part of a MOS transistor.

### 2. Description of Related Art

A conventional art disclosed in US Patent Publication No. 20130249017 related a nonvolatile memory device and a method of fabricating the same. The nonvolatile memory device includes a memory cell having a transistor in which an insulating isolation layer is formed in a channel region. The nonvolatile memory device includes a metal-oxide-semiconductor (MOS) transistor as a basic component. An insulating isolation layer is formed in at least a channel region, and a gate insulating layer includes an insulating layer or a variable resistor and serves as a data storage. A gate includes a metal layer formed in a lower portion thereof. A first source and a drain region are lightly doped with a dopant, and a second source and a drain region are heavily doped with a dopant. Alternatively, the nonvolatile memory device includes a MOS transistor serving as a basic component. The MOS transistor includes at least a channel region in which an insulating isolation layer is formed, and a gate insulating layer includes an insulating layer or a variable resistor and serves as a data storage. The gate includes a conductive layer, a first and a second source region form a diode, and a first and a second drain region form a diode.

A conventional art disclosed in Korean Patent Publication No. 2001-0056831 relates to a method of forming an anti-fuse of a semiconductor device, more specifically, a method of forming an anti-fuse of a semiconductor device, which may easily break an insulating layer at a lower voltage using a right-angled corner of a semiconductor substrate. The disclosed method includes forming a predetermined pattern on a semiconductor substrate on which a process for a lower structure is completely performed to form a structure having right-angled corners, depositing a gate oxide layer and stacking a nitride layer and a first polycrystalline silicon (poly-Si) layer on the gate oxide layer, forming a photoresist pattern to expose the first poly-Si layer formed on the right-angled corners of the semiconductor substrate, dry etching the exposed first poly-Si layer to firstly expose the nitride layer formed on the right-angled corners of the semiconductor substrate, dry etching the nitride layer, and depositing a second poly-Si layer and forming a pattern. In the above-described method of forming the anti-fuse of the semiconductor device, an anti-fuse capable of easily breaking an insulating layer at a lower voltage may be fabricated.

Another conventional art disclosed in Korean Patent Publication No. 1997-0067848 relates to a semiconductor memory device and a method of fabricating the same. The semiconductor memory device includes an access transistor T configured to access information of word lines, a storage node capacitor C configured to store information stored through a bit line due to an operation of the access transistor T, and a charge-up transistor P configured to supply charges to the storage node capacitor C. In the above-described semiconductor memory device, charges may be continuously supplied to the storage node capacitor C so that processing speed of the semiconductor memory device can be improved.

Meanwhile, a nonvolatile semiconductor memory device may be a semiconductor memory device in which information stored in a memory cell is retained even if power supply is interrupted.

The nonvolatile memory device may be electrically programmed. The nonvolatile memory device may include memory cells in which storage layers include insulating layers or variable resistors.

When the storage layers include the insulating layers, a high voltage for a program operation may be applied to both electrodes (i.e., a first electrode and a second electrode) between the insulating layers to cause a breakdown. In this case, a resistive path may be generated so that the insulating layers may be changed from an insulation state to a conduction state. Accordingly, the insulating layers may become anti-fuses. When the insulating layers are in the conduction state, the nonvolatile memory device may be in a programmed state, and the programmed state may be defined as storage of data ‘0.’ Also, when the insulating layers are in the insulation state, the nonvolatile memory device may be in an unprogrammed state, and the unprogrammed state may be defined as storage of data ‘1.’

Conversely, the conduction state may be defined as data ‘1,’ and the insulation state may be defined as data ‘0.’

When the storage layers are the variable resistors, the variable resistors may include a resistance variable material or a phase transition material.

In a case in which the variable resistors of the memory cell include the resistance variable material, when a voltage equal to or higher than a set voltage is applied to both electrodes (i.e., a first electrode and a second electrode) between the variable resistors, the variable resistors may be put into a low resistance state, and when a voltage equal to or higher than a rest voltage is applied to the first and the second electrodes between the variable resistors, the variable resistors may be put into a high resistance state. Accordingly, the low resistance state may be defined as storage of data ‘0,’ and the high resistance state may be defined as storage of data ‘1.’ Conversely, the low resistance state may be defined as storage of data ‘1,’ and the high resistance state may be defined as storage of data ‘0.’

The resistance variable material is being developed using various materials, such as perovskite, transition metal oxides, and chalcogenides.

Memory devices using the resistance variable material may be classified into several types according to materials. A first type is a memory device in which a colossal magnetoresistance (CMR) material, such as Pr₁₋ₓCaₓMnO₃ (PCMO), is inserted between electrodes, and a variation in resistance due to an electric field is used. A second type is a memory device in which a binary oxide, such as niobium oxide (Nb₂O₅), titanium oxide (TiO₂), nickel oxide (NiO), or aluminum oxide (Al₂O₃), is prepared to have a nonstoichiometric composition and used as a resistance variable material. A third type is a memory device in which a chalcogenide material maintains an amorphous structure, and a difference in resistance due to a variation in the threshold voltage of an ovonic switch is used, instead of supplying a large current to the chalcogenide material to change the phase of the chalcogenide material as in a phase-change random access memory (PRAM). A fourth type is a memory device in which a ferroelectric material, such as strontium titanium oxide (SrTiO₃) or strontium zirconium oxide (SrZrO₃), is doped with chromium (Cr) or Nb to change a resistance state. A final type is a memory device including programmable metallization cells (PMCs) in which silver (Ag) having a high ion mobility is doped into a solid electrolyte, such as germanium selenium (GeSe), so that two resistance states are formed depending on whether or not a conductive channel is formed in a medium due to an electrochemical reaction. In addition, materials or fabrication processes capable of embodying two stable resistance states to obtain memory characteristics have been reported.

In a case in which the variable resistors of the memory cell include the phase transition material, when the phase transition material is in a low resistance state, the low resistance state may be defined as storage of data ‘0,’ and when the phase transition material is in a high resistance state, the high resistance state may be defined as storage of data ‘1.’ Conversely, the low resistance state may be defined as storage of data ‘1,’ and the high resistance state may be defined as storage of data ‘0.’

The phase transition material may be changed into a crystalline phase or an amorphous phase due to a predetermined current. The crystalline phase may correspond to the low resistance state, and the amorphous phase may correspond to the high resistance state.

According to the conventional techniques, since a MOS transistor and a storage element should be formed in a memory cell, the fabrication process becomes relatively intricate. Also, since a footprint of the memory cell is big, there is a fundamental limit to increasing the integration density of memory devices.

### SUMMARY

Embodiments of the inventive concept provide a semiconductor device that includes a transistor characterized by smaller area structure and, therefore, higher integration density than in the conventional art.

Other embodiments of the inventive concept provide methods of operating and fabricating the semiconductor device.

Furthermore, other embodiments of the inventive concept provide a memory cell including the semiconductor device, a semiconductor memory device including the memory cell, and a method of operating the memory array. Also, it may be easily understood that aspects and advantages of the inventive concept may be realized by units described in the claims and combinations thereof.

The technical objectives of the inventive disclosure are not limited to the above disclosure. Other objectives may become apparent to those of ordinary skill in the art based on the following descriptions.

In accordance with an aspect of the inventive concept, a semiconductor device includes a semiconductor substrate, a first and a second diffusion region formed under a surface of the semiconductor substrate, a gate stacked on the semiconductor substrate, the first diffusion region is at least one active region not being intersected by the gate and the sidewall spacer, wherein the second diffusion region may include a part of an active region intersecting the gate and the sidewall spacer, wherein there is no gate insulating layer between the gate and the semiconductor substrate.

A portion of the second diffusion region between the gate and the first diffusion region is formed by self-alignment.

The semiconductor device may be configured with another semiconductor device by sharing at least the first diffusion region.

The semiconductor device may be configured with another semiconductor device by sharing at least the gate.

The semiconductor device further includes a third diffusion region in an upper section of the second diffusion region, wherein the third diffusion region includes a part of an active region intersecting the gate.

The semiconductor device further includes a fifth diffusion region between the first and the second diffusion regions, wherein the fifth diffusion region includes a part of an active region intersecting the sidewall spacer.

The gate and the second diffusion region may form a diode. The first and the second diffusion regions may form a diode.

The third and the second diffusion regions may form a diode.

A fourth diffusion region or buried oxide layer may be formed below the first diffusion region or the second diffusion region.

The gate, the second diffusion region, and the first diffusion region may form a bipolar junction transistor. The second diffusion region may be a base of the bipolar junction transistor.

The third diffusion, the second diffusion region, and the first diffusion region may form a bipolar junction transistor. The second diffusion region may be a base of the bipolar junction transistor.

A contact hole is additionally formed on the first diffusion region, the gate or both as well as filled with a conductive material. A storage bottom electrode, a storage layer, and a storage top electrode are additionally formed on the conductive material connected to the first diffusion region, the conductive material connected to the gate, or both.

A gate electrode connected to the gate is connected to a source line or a bit line.

Set or reset operations may be performed by applying reverse-bias breakdown to the diode in order to switch a current flow in the storage layer.

The storage layer may include an insulating layer or a variable resistor. The variable resistor may include a material with characteristics to be in a low resistance state or high resistance state according to a voltage or a current applied thereto, for example, the variable resistor includes a phase change material, a resistance variable material, or a resistance variable material by magnetic orientation, includes a data storage element of Phase Change Random Access Memory (PCRAM), Resistive Random Access Memory (ReRAM), or Magnetic Random Access Memory (MRAM), and includes an MTJ (Magnetic Tunnel Junction).

The storage top electrode may be connected to a bit line or a source line A method of fabricating a semiconductor device includes forming a first and second diffusion region in a semiconductor substrate and forming a gate on the semiconductor substrate.

The method of fabrication may further include forming a third diffusion region in the semiconductor substrate.

The method of fabrication may further include forming a fifth diffusion region in the semiconductor substrate

In accordance with an aspect of the inventive concept, the method of fabrication may further include forming an ohmic contact between the gate and the semiconductor substrate.

Specific particulars of other embodiments are included in detailed descriptions and drawings.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIG. 1A is a cross-sectional view of a semiconductor device according to an embodiment of the inventive concept;

FIG. 1B is a cross-sectional view of a semiconductor device according to another embodiment of the inventive concept;

FIG. 1C is a cross-sectional view of a semiconductor device according to another embodiment of the inventive concept;

FIG. 2A is a cross-sectional view of a memory cell according to another embodiment of the inventive concept;

FIG. 2B is a cross-sectional view of a memory cell according to another embodiment of the inventive concept;

FIG. 3A is a cross-sectional view of two memory cells according to another embodiment of the inventive concept;

FIG. 4A is a cross-sectional view illustrating preparation of a semiconductor substrate with a fourth diffusion region to fabricate a semiconductor device according to an embodiment of the inventive concept;

FIG. 4B is a cross-sectional view illustrating formation of a second diffusion region to fabricate a semiconductor device according to an embodiment of the inventive concept;

FIG. 4C is a cross-sectional view illustrating formation of a gate to fabricate a semiconductor device according to an embodiment of the inventive concept;

FIG. 4D is a cross-sectional view illustrating formation of sidewall spacers to fabricate a semiconductor device according to an embodiment of the inventive concept;

FIG. 4E is a cross-sectional view illustrating formation of a first diffusion region to fabricate a semiconductor device according to an embodiment of the inventive concept;

FIG. 4F is a cross-sectional view illustrating removal of a gate to fabricate a semiconductor device according to an embodiment of the inventive concept;

FIG. 4G is a cross-sectional view illustrating formation of a third diffusion region to fabricate a semiconductor device according to an embodiment of the inventive concept;

FIG. 4H is a cross-sectional view illustrating deposition of a conductive material in contact holes to fabricate a semiconductor device according to an embodiment of the inventive concept;

FIG. 4I is a cross-sectional view illustrating formation of a fifth diffusion region to fabricate a semiconductor device according to an embodiment of the inventive concept;

FIG. 4J is a cross-sectional view illustrating formation of a silicide layer to fabricate a semiconductor device according to an embodiment of the inventive concept;

FIG. 5A is a circuit diagram of a memory cell according to an embodiment of the inventive concept;

FIG. 6A is a circuit diagram of memory cells according to another embodiment of the inventive concept;

FIG. 7A is a construction diagram of the entire memory device according to an embodiment of the inventive concept.

### DETAILED DESCRIPTION OF THE EMBODIMENTS

The inventive concept will now be described more fully hereinafter with reference to the accompanying drawings, in which embodiments of the inventive concept are shown. This inventive concept may, however, be embodied in different forms and should not be construed as limited to the embodiments set forth herein. Rather, these embodiments are provided so that this disclosure is thorough, complete, and fully conveys the scope of the inventive concept to one skilled in the art.

The following detailed description is merely exemplary in nature and is not intended to limit the application and uses contemplated herein. Furthermore, there is no intention to be bound by any theory presented in the preceding background or the following detailed description.

The inventive concept will now be described more fully hereinafter with reference to the accompanying drawings, in which embodiments of the inventive concept are shown.

A structure according to the inventive concept may be formed on a semiconductor substrate including a bulk silicon wafer or a silicon thin layer disposed on an insulating layer (typically referred to as a silicon-on-insulator (SOI)).

Hereinafter, a state in which a resistive path is not present in a storage layer of a memory cell will be defined as data ‘0,’ and a state in which the resistive path is formed in the storage of the memory cell will be defined as data ‘1.’ The inventive concept is not limited thereto. For example, the state in which the resistance path is not present may be defined as data ‘1,’ and the state in which the resistance path is formed may be defined as data ‘0.’

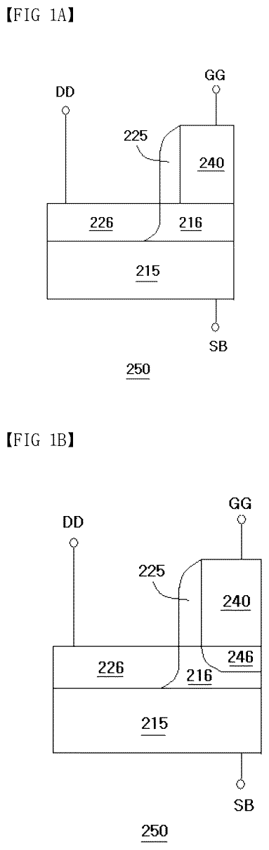

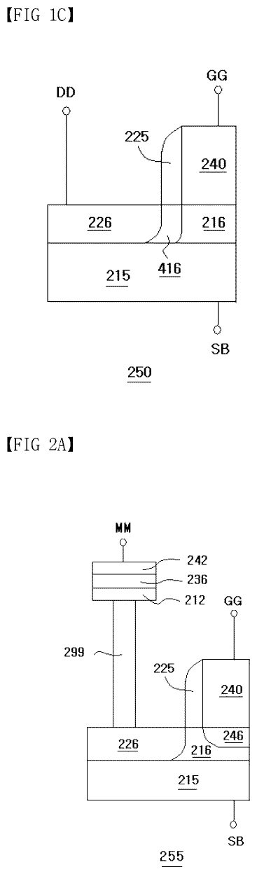

FIG. 1A is a cross-sectional view of a semiconductor device 250 according to an embodiment of the inventive concept.

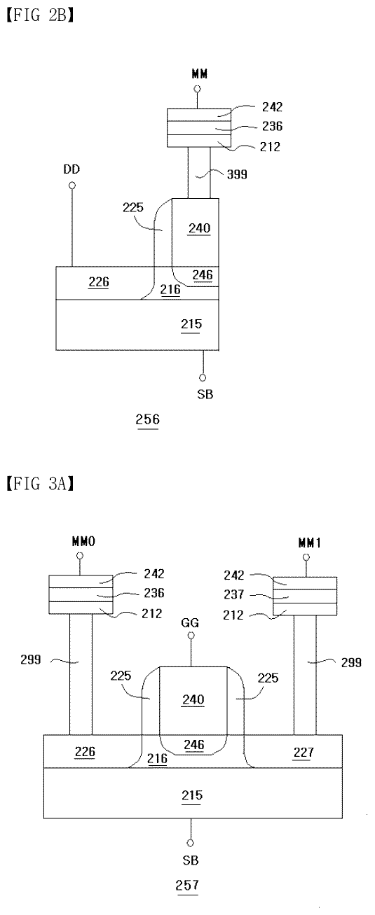

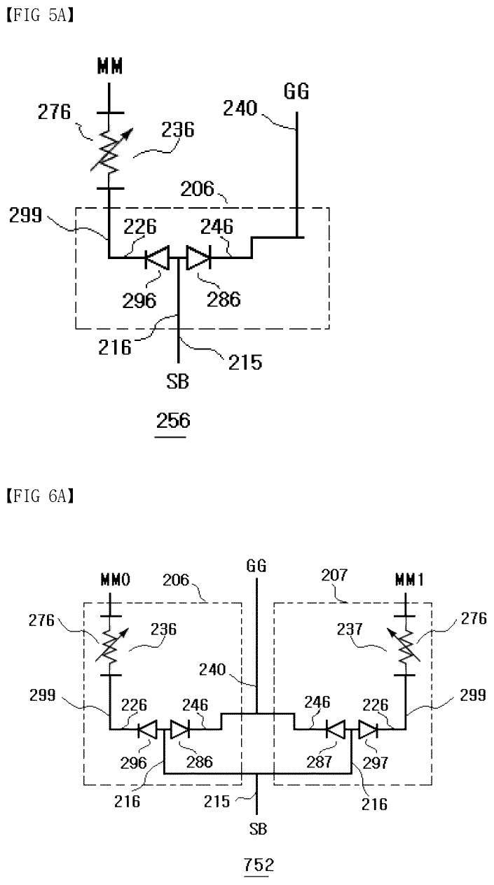

FIG. 5A is a circuit diagram of the semiconductor device 255 shown in FIG. 2A, according to an embodiment of the inventive concept.

As shown in FIG. 1A, the semiconductor device 250 according to the embodiment of the inventive concept may include a part of a MOS transistor.

The semiconductor device 250 shown in FIG. 1A may include a part of a MOS transistor similar to a typical MOS transistor as a basic component. Specifically, the semiconductor device 250 may include a fourth diffusion region 215, a gate 240 stacked without a gate insulator on the semiconductor substrate, a gate electrode GG connected to the gate 240, sidewall spacers 225 formed on sidewalls of the gate 240, a first diffusion region 226, and a first diffusion electrode DD connected to the first diffusion region 226.

Although the present embodiment pertains to an example in which sidewall spacers are formed, the inventive concept is not limited thereto and may be applied to a modified example in which sidewall spacers are not formed.

As shown in FIG. 1A, the first diffusion region 226 is at least one active region, which may not intersect the gate 240 and the sidewall spacer 225. The second diffusion region 216 may refer to a region of an active region, which may intersect the gate 240 or the sidewall spacer 225. The second diffusion region 216 may be doped with a dopant complementary to the first diffusion region. Thus, the first and the second diffusion regions 226, 216 may form a diode.

As shown in FIG. 1A, a fourth diffusion region 215 may be formed below the first and the second diffusion region 226, 216. The fourth diffusion region 215 may be doped with a dopant equivalent or similar to that used for the second diffusion region 216.

Although in the case that the buried oxide is formed, the semiconductor device may be formed on or in a semiconductor substrate including a SOI instead of a semiconductor substrate including a bulk silicon wafer, the inventive concept is not limited to the semiconductor substrate including the SOI.

The gate 240 may be a conductive layer, and the gate 240 may be stacked without a gate insulating layer on the semiconductor substrate.

As shown in FIG. 1A, the gate 240 may include a conductive layer formed from a metal, a silicide, a metal compound, or poly-Si. Like a typical transistor, the gate 240 may include a conductive layer formed from poly-Si.

In FIG. 1A, the fourth diffusion region 215 may be typically doped with a P-type or N-type dopant.

In an embodiment of the inventive concept, it is assumed that the fourth diffusion region 215 is a P type. Accordingly, the first region 226 may become an N-type semiconductor that is doped with a complementary dopant to the fourth diffusion region 215, and the second diffusion region 216 may become a P-type semiconductor that is doped with a dopant equivalent or similar to that used for the fourth diffusion region 215.

The first and the second diffusion region 226, 216 may be formed from, for example, an N-type semiconductor and a P-type semiconductor, respectively, and constitute a PN junction diode structure. Conversely, the first and the second diffusion region 226, 216 may be formed from a P-type dopant and an N-type dopant, respectively, and constitute a PN junction diode structure.

The gate 240 is to be formed with poly-Si implanted by an N-type dopant complementary to the second diffusion region 216, thereby forming a diode between the gate 240 and the diffusion region 216.

The gate 240, the second diffusion region 216 and the first diffusion region 226 may form a bipolar junction transistor. The second diffusion region 216 form a base of the bipolar junction transistor. The diode or the bipolar junction transistor may be used for accessing a storage layer.

As is widely known to one skilled in the art, when a lightly doped semiconductor is in contact with a metal, a Schottky diode may be formed.

Furthermore, in another embodiment of the inventive concept, the first and the second diffusion region 226, 217 may be formed from a semiconductor lightly doped with a dopant equivalent or similar to that used for the first or the second diffusion region, the first diffusion electrode DD connected to the first diffusion region may be formed from silicide or a metal, and Schottky diode structures may be formed.

Referring to FIG. 1A, according to an embodiment of the inventive concept, the first and the second diffusion region 226, 216 may be formed from a semiconductor and a metal, respectively, and form a Schottky diode. That is, the second diffusion region 216 may be formed from a semiconductor lightly doped with a dopant, and the first diffusion region 226 may be formed from silicide. Conversely, the first and the second diffusion region 226 and 216 may be formed form a metal and a semiconductor, respectively, and form a Schottky diode.

The formation of the diode structure according to the present invention is not limited to the above description.

According to another embodiment of the inventive concept, a third diffusion region may be additionally formed in an upper section of the second diffusion region, wherein the third diffusion region includes a part of an active region intersecting the gate. The embodiment is shown in FIG. 1B.

As compared with FIG. 1A, FIG. 1B shows the third diffusion 246 may be additionally formed in an upper section of the second diffusion region 216, wherein the third diffusion region 246 includes a part of an active region intersecting the gate 240. The third diffusion region 246 may be formed by an ion implantation with an N-type dopant complementary to the second diffusion region 216. The third diffusion region 246 and the second diffusion region 216 may form a diode.

The gate 240 is to be implanted with an N-type dopant equivalent or similar to that used for the third diffusion region 246 in case that the gate 240 is formed with a poly-Si because the gate 240 is to have an ohmic contact with the third diffusion region 246. The other cases, silicide between the gate 240 and the third diffusion region 246 is to be formed.

According to another embodiment of the inventive concept, a fifth diffusion region between the first and the second diffusion regions may be formed, wherein the fifth diffusion region includes a part of an active region intersecting the sidewall spacer. The embodiment is shown in FIG. 1C.

As compared with FIG. 1A, FIG. 1C shows the fifth diffusion region 416 between the first and the second diffusion regions 226, 216 may be additionally formed, wherein the fifth diffusion region 416 includes a part of an active region intersecting the sidewall spacers 225.

The fifth diffusion region 416 is to be formed by an ion implantation with a P-type dopant equivalent or similar to that used for the second diffusion region 216. It may be self-aligned with the gate 240.

As compared with FIG. 1B, FIG. 2A shows a memory cell 255 in which a storage layer 236 with top and bottom electrodes 242, 212 is additionally formed. The storage layer 236 is placed between the top and bottom electrodes 242, 212. The top electrode 242 is connected to a storage electrode MM and the bottom electrode 212 is connected to a contact hole 299 connected to a first diffusion region 226. The contact hole 299 may be multiple levels of contact holes stacked to connect with multiple levels of conductive layers.

As compared with FIG. 1B, FIG. 2B shows a memory cell 256 in which a storage layer 236 with top and bottom electrodes 242, 212 is additionally formed. The storage layer 236 is placed between the top and bottom electrodes 242, 212. The top electrode 242 is connected to a storage electrode MM and the bottom electrode 212 is connected to a contact hole 399 connected to a gate 240. The contact hole 399 may be multiple levels of contact holes stacked to connect with multiple levels of conductive layers.

There are several configurations to form an array with memory cells.

In an embodiment of the inventive concept, the memory cell may share at least its gate with the adjacent memory cell. These embodiments are shown in FIG. 3A. As shown in FIG. 3A, a gate is shared.

As shown in FIG. 3A, a gate electrode GG is connected to the shared gate 240, there are storage electrodes MM0, MM1 and storage layers 236, 237.

Furthermore, in another embodiment of the inventive concept, the memory cell may share at least its first diffusion region with the adjacent memory cell.

Since the above-described modified embodiments may be easily understood by one skilled in the art, a detailed description thereof will be omitted here. However, the present inventive concept should be interpreted as including various modified embodiments.

A method of fabricating a semiconductor device according to the inventive concept may include forming a first and second diffusion region in a semiconductor substrate and forming a gate on the semiconductor substrate.

The method of fabricating the memory device according to the inventive concept may further include forming a third diffusion region in the semiconductor substrate.

Various methods for fabricating typical MOS transistors are widely known. Accordingly, conventional methods will be only briefly described for clarity, and some known methods will be wholly omitted.

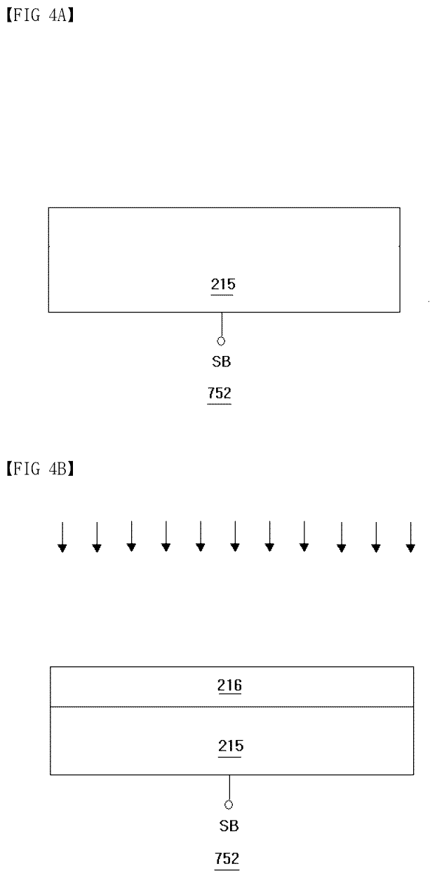

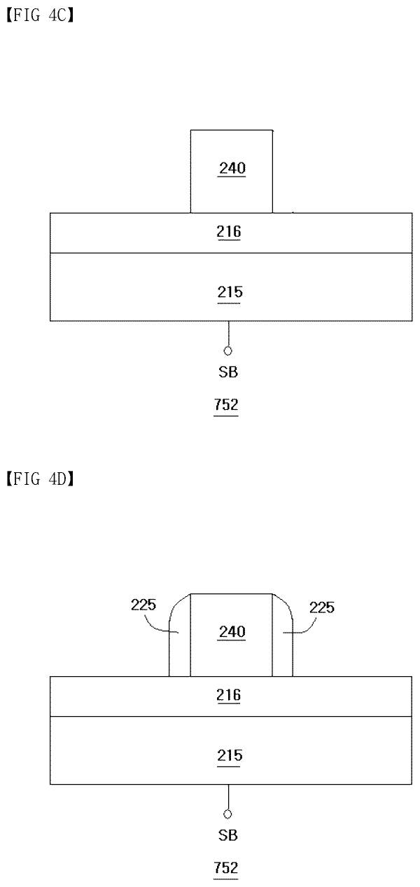

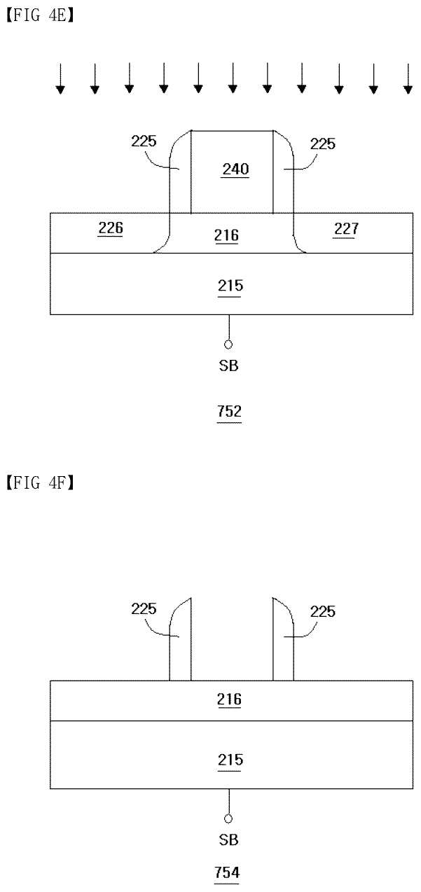

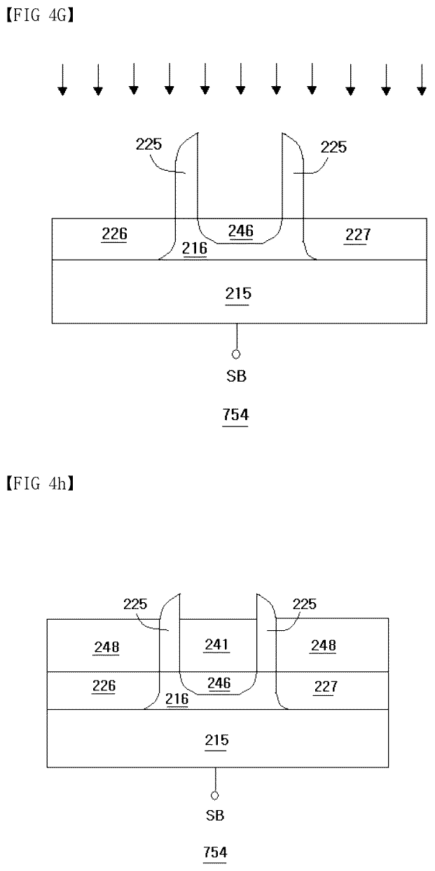

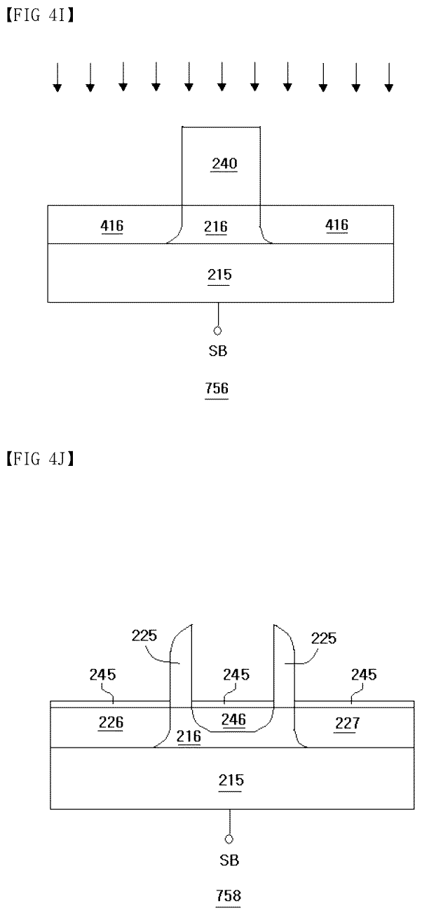

A method of fabricating a semiconductor device according to an embodiment of the inventive concept is illustrated in FIGS. 4A through 4J.

The method of fabricating the semiconductor device according to the embodiment of the inventive concept may start from an operation of preparing a semiconductor substrate with a fourth diffusion region 215, as shown in FIG. 4A.

The semiconductor substrate may be a single crystalline silicon substrate. Although the present embodiment pertains to an example in which a bulk silicon wafer is used, the inventive concept is not limited thereto.

The fourth diffusion region 215 may be a P-type well doped with a P-type dopant or an N-type well doped with an N-type dopant. In the present embodiment, it is assumed that the fourth diffusion region 215 is the P-type well doped with the P-type dopant.

Thereafter, as shown in FIG. 4B, a second diffusion region 216 may be formed. As described above, the second diffusion region 216 may be doped with a dopant equivalent or similar to that used for the fourth diffusion region 215. Therefore, the second diffusion 216 may be a P-type semiconductor. Accordingly, a P-type dopant may be implanted into the second diffusion region 216 in the arrow direction shown in FIG. 4B.

The second diffusion region 216 may be implanted with ions to have about 1 to 1.5 times the depth of first diffusion regions to be subsequently formed. For example, when the first diffusion regions have a depth of about 0.2 μm, the second diffusion region 216 may have a depth of about 0.2 μm to about 0.3 μm.

Thereafter, referring to FIG. 4C, a gate 240 may be formed on the semiconductor substrate. In an embodiment of the inventive concept, the conductive layer 240 may be formed from poly-Si. As shown in FIG. 4C, a gate 240 may be deposited using poly-Si on the semiconductor substrate, and the conductive layer 240 formed from poly-Si may be patterned using etching and photolithography processes.

Thereafter, referring to FIG. 4D, after the patterning process, heat may be applied in an oxidation atmosphere so that a silicon oxide thin layer (not shown) can be thermally grown on sidewalls of the gate 240 to form sidewall spacers 225.

Although the present embodiment pertains to an example in which the sidewall spacers 225 are formed, the inventive concept is not limited thereto and may be applied to a modified example in which sidewall spacers are not formed.

Thereafter, as shown in FIG. 4E, a dopant may be implanted in the arrow direction to form first diffusion regions 226, 227.

Since the first diffusion regions 226, 227 should be doped with a dopant that is complementary to the second diffusion regions 216, 217, an N-type dopant may be ion-implanted into the first diffusion regions 226, 227 in the present embodiment of the inventive concept.

As described above, according to the embodiments of the inventive concept, the first diffusion regions 226, 227 may be ion-implanted by self-alignment conforming to the gate 240 and the sidewall spacer 225. This is because the gate 240 and the sidewall spacer may serve as an ion implantation mask.

According to another embodiment of inventive concept, the method of fabricating the semiconductor device further includes forming a third diffusion region in the semiconductor substrate.

The embodiment is shown in FIGS. 4F, 4G, 4H. As shown in FIG. 4F, the gate shown in FIG. 4C is removed. A removal of the gate is to be accomplished through an etching process. Thickness of remained sidewall spacers 225 may be thicker through thermal growth to obtain better isolation (not shown). Thereafter, as shown in FIG. 4G, an N-type dopant complementary to the second diffusion region 216 may be implanted in the arrow direction to form a third diffusion region 246 and first diffusion regions 226, 227.

The third diffusion region 246 may be implanted with ions to have about 0.5 to 1 times the depth of a first diffusion region. For example, when the first diffusion regions 226, 227 have a depth of about 0.2 μm, the second diffusion region 216 may have a depth of about 0.1 μm to about 0.2 μm.

Thereafter, as shown in FIG. 4H, conductive material may be deposited in contact holes 241, 248. The conductive material is a poly-Si in this embodiment. Thereafter, an N-type dopant equivalent or similar to that used for the first and the third diffusion region may be implanted into the poly-Si to form ohmic contacts with the first and the third diffusion region (not shown).

According to another embodiment of inventive concept, the method of fabricating the semiconductor device further includes forming a fifth diffusion region in the semiconductor substrate.

The embodiment is shown in FIG. 4I. As shown in FIG. 4I, a P-type dopant equivalent or similar to that used for the second diffusion region 216 may be implanted in the arrow direction to form a fifth diffusion region 416 after forming the gate shown in FIG. 4C.

According to another embodiment of the inventive concept, the method of fabricating the semiconductor device further includes forming an ohmic contact between the gate and the semiconductor substrate.

The embodiment is shown in FIG. 4J. As shown in FIG. 4J, a silicide layer 245 is deposited in contact holes on the semiconductor substrate to form the ohmic contact after forming the third diffusion region shown in FIG. 4G. The third diffusion region 246 is to be heavily doped. Thereafter, a conductive material (not shown) is deposited on the silicide layer 245.

Finally, the fabrication of the memory according to the inventive concept may be completed by known process operations (not shown) of, for example, depositing a dielectric material layer, etching openings through the dielectric material layer to expose portions of the first diffusion region, and forming metallized portions which are to extend through the openings and thereby become electrically connected to the first diffusion region.

FIG. 5A is an equivalent circuit diagram of the memory cells shown in FIG. 2A, according to an embodiment of the inventive concept, and FIG. 6A is an equivalent circuit diagram of the memory cells shown in FIG. 3A.

In accordance with an aspect of the inventive concept, the gate, second diffusion regions and the first diffusion region may form a bipolar junction transistor.

As shown in 5A, a storage layer 236 shown in FIG. 2A may be simply represented as a variable resistor 276 because it is an insulating layer or a variable resistor layer. In FIG. 2A, an embodiment of the inventive concept is a case with a fourth diffusion region, instead of buried oxide layer. A diode structure between a third diffusion region 246 and a second diffusion 216 in FIG. 2A may be represented as a first diode 286 in FIG. 5A. The third diffusion region 246 has an ohmic contact with a gate 240. A diode structure between a first diffusion region 226 and a second diffusion region 216 in FIG. 2A may be represented as a second diode 296 in FIG. 5A. The first and the second diodes 286, 296 may be a bipolar junction transistor.

Typically, when the storage layer 236 is an oxide layer, a VCC voltage may be adjusted such that an electric field of about 5 MV/cm is applied to the oxide layer 236. Also, to cause a oxide breakdown in the oxide layer 236 and generate a resistive path, a VCC voltage may be adjusted such that an electric field of about 20 MV/cm is applied to the oxide 236.

For example, assuming that the oxide layer has a thickness of about 2.3 nm in a process using a gate length of about 130 nm, a VCC voltage may be about 1.2 V, and a VPP voltage required for generating a resistive path may be about 5 V.

Accordingly, in the above-described example, a VPP voltage for a program operation may be about 6V considering a diode threshold.

Hereinafter, a case in which the storage layer 236 is an insulating layer will be referred to as an A-type, and a case in which the storage layer 236 is a variable resistor will be referred to as a B-type.

A semiconductor device including an A-type memory cell and a method of operating the same may be similar to a nonvolatile memory including a B-type memory cell and a method of operating the same except that, in the A-type memory cell, it is difficult to change an insulating layer from a low resistance state (LRS) into a high resistance state (HRS), unlike a variable resistor. Thus, since the above-described circuit and operation of the memory device including the A-type memory cell according to an embodiment of the inventive concept may be easily applied to a circuit and operation of a memory device including a B-type memory cell, a repeated description will be omitted for brevity.

For example, the above-described VPP voltage, which is a program voltage, may be a voltage required to generate a resistive path in a insulating layer and change the insulating layer from an HRS into an LRS.

Similarly, a set voltage may change a variable resistor from an HRS into an LRS.

Accordingly, the VPP voltage serving as the program voltage may be adjusted to be the set voltage (VSET) for the variable resistor, and a program operation may be performed in a similar manner to the case in which the memory device includes the A-type memory cell.

Furthermore, in unipolar case, the VPP voltage, which is the program voltage, may be adjusted to be a reset voltage (VRESET) and send the variable resistor from an LRS into an HRS.

But, in a bipolar switch case, a voltage polarity across the variable resistor for set should reverse with a voltage polarity for reset.

A set and reset operation of a memory according to an embodiment of the inventive concept will described in the case that a storage layer operates with bipolar switching.

In the case of using a diode for bipolar switching bias across the storage layer according to another embodiment of the inventive concept, a set or reset operations may be performed by applying reverse-bias breakdown to the diode in order to switch a current flow in the storage layer.

FIG. 6A is an equivalent circuit diagram of the memory cells shown in FIG. 3A.

As shown in FIG. 6A, two memory cells 206, 207 are illustrated. Set and reset operations may selectively performed in memory cells. When 0V and VRESET voltage are applied to storage electrodes MM0, MM1, respectively, and VSEL voltage is applied to a fourth diffusion electrode SB, and VSET voltage is applied to a gate electrodes GG, an NPN bipolar junction transistor including a first and a second diodes 286, 296 is in operating condition. Thus, the current of the bipolar junction transistor flows toward MM0, and VSET voltage with dropped diode threshold voltage across a first storage layer is applied. Therefore, the first storage layer 276 is in an LRS.

When floating and VRESET voltage are applied to storage electrodes MM0, MM1, respectively, and VSEL voltage is applied to a fourth diffusion electrode SB, and 0V is applied to a gate electrode GG, another NPN bipolar junction transistor including the first and the second diodes 287, 297 is in operating condition. Thus, the current of the bipolar junction transistor flows toward GG, and VRESET voltage with dropped bipolar saturation voltage across a second storage layer 297 is applied with opposite current flow of set. Therefore, the second storage layer 376 is in an HRS.

In FIG. 6A, read may operate. When OV voltage is applied to storage electrodes MM0, MM1, and VCC voltage is applied to a gate electrode GG and a fourth diffusion electrode SB, a NPN bipolar junction transistor including a first and a second diodes 286, 296 is in operating condition and the first storage layer 276 is in an LRS. Thus, the current flows toward MM0. But the second storage layer 297 is in an HRS. Thus, the current does not flow toward MM1.

Accordingly, the resistance state of the storage layer can be converted to digital signal through a read circuitry to sense the current.

The fourth diffusion electrode may serve as a word line. The gate electrode GG may serve as a source line. Each of storage electrodes MM0, MM1 may serve as a bit line.

In an opposite case, a gate electrode GG may serve as a bit line, storage electrodes MM0, MM1 may serve as a source line.

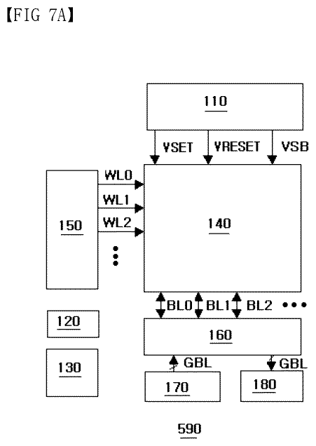

FIG. 7A shows the overall configuration of a memory device according to an embodiment of the inventive concept.

The overall memory device according to the inventive concept may include a memory array in which a plurality of memory cells are arranged; an internal supply unit configured to generate a voltage VSET, VRESET, and VSB used for the memory array; a row decoder configured to select a word line from the memory array; a column decoder configured to select a bit line; a write circuit configured to receive a data bus from an input/output (I/O) unit and transmit the data bus to a global bit line bus GBL under the control of a controller; a read circuit required for a read operation including transmitting stored data to the global bit line bus GBL, sensing and amplifying an electrical state of the global bit line bus using a sense amplifier, converting the sensed and amplified electrical state into a digital signal, and transmitting the digital signal to the I/O unit; a controller configured to control the inside of the memory device; and the I/O unit configured to allow the outside of the memory device to interface with the inside of the memory device.

The configuration of the memory device will now be briefly described. The memory device may include the above-described memory array 140 and an internal supply unit 110 configured to generate the voltage VSET, VRESET, and VSB required for the set and reset operation.

Furthermore, the memory device may include the row decoder 150 configured to select a word line for the memory array 140 and the column decoder 160 configured to select a bit line.

Referring to FIG. 7A, the row decoder 150 and the column decoder 160 may receive an address bus from the I/O unit 130, be controlled by a controller 120, and decode an address.

The memory device may include the write circuit 170 used for a data write operation. The write circuit 170 may receive the data from the I/O unit 130 and transmit the data to the global bit line bus GBL (GBL0, GBL1, GBL2, . . . ) under the control of the controller 120.

Referring to FIG. 7A, the memory device may include a read circuit 180 required for a data read operation. Stored data may be transmitted to the global bit line bus GBL (GBL0, GBL1, GBL2, . . . ) , and a sense amplifier 181 in the read circuit 180 may sense and amplify an electrical state of the global bit line bus GBL, convert the sensed and amplified electrical state into a digital signal, and transmit the digital signal to the I/O unit 130.

The I/O unit 130 may allow the outside of the memory device to interface with the inside thereof. The controller 120 may receive commands required for the write and read operations from the I/O device 130, analyze the commands in detail, and control circuits related with the commands.

Construction of the memory device according to the embodiment of the inventive concept may be modified. For example, the semiconductor device is not limited to a one-time programmable (OTP) device and a multi-time programmable (MTP) device and may be used for a storage device storing information on a redundancy repair including a fuse, which may be used in various semiconductor devices, such as a dynamic random access memory (DRAM) or a static random access memory (SRAM). Also, it may be used for programmable logic device(PLD), field programmable gate array (FPGA) and integrated circuits.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this inventive concept as defined in the claims. In the claims, means-plus-function clauses are intended to cover the structures described herein as performing the recited function, and not only structural equivalents but also equivalent structures.

What is claimed is:

1. A method of fabricating a semiconductor device, comprising:
forming a first and a second diffusion region in a semiconductor substrate; and
forming a gate on the semiconductor substrate.

2. The method of claim 1, further comprising:
forming a third diffusion region in the semiconductor substrate.

3. The method of claim 1, further comprising:
forming a fifth diffusion region in the semiconductor substrate.

4. The method of claim 1, further comprising:
forming an ohmic contact between the gate and the semiconductor substrate.
